(19) United States
(12) Patent Application Publication
(10) Pub. No.: US 2006/0124957 A1
(43) Pub. Date: Jun. 15, 2006

(54) Single-phase converter module

(76) Inventors: Stefan Hornung, Leinfelden-Echterdingen (DE); Peter Urbach, Reutlingen (DE); Barbara Will, Herrenberg (DE)

Correspondence Address: KENYON & KENYON LLP, ONE BROADWAY, NEW YORK, NY, 10004, US

(21) Appl. No.: 10/538,269

(22) PCT Filed: Jun. 12, 2003
(86) PCT No.: PCT/DE03/01963

§ 371 Date: Nov. 28, 2005

(30) Foreign Application Priority Data
Dec. 12, 2002 (DE) 102 58 035.9

(51) Int. Cl. H01L 29/74

(52) U.S. Cl. 257/107

(57) ABSTRACT

A converter module is described having a positive terminal (2), a negative terminal (4), and a phase terminal (3), as well as a first semiconductor chip (9) and a second semiconductor chip (9), the terminals (2-4) and the semiconductor chips (9) being situated on top of one another in a stack. A particularly simple and cost-effective converter module may produced in that the positive terminal (2), the negative terminal (4), or the phase terminal (3) are made up of a contact plate (5), including a bar-shaped terminal lug (6) which is positioned asymmetrically on the contact plate (5), and an auxiliary element (7) is provided at its end which prevents the terminal (2-4) from tilting.

### FIELD OF THE INVENTION

The present invention relates to a converter module having a component/contact stack configuration, and a method for manufacturing such a converter module.

### BACKGROUND INFORMATION

Converters are used for converting electric power by using converter valves such as, for example, diodes, thyristors, transistors, etc. They are configured as rectifiers, inverters, or converters, depending on the application. In the automotive field, converters are used in particular as rectifiers which convert an A.C. voltage, supplied by a vehicle generator, into a D.C. voltage for supplying a vehicle electrical system.

A conventional rectifier is illustrated in FIG. 1 as an example. FIG. 1 shows a rectifier bridge circuit for an alternator, which converts the alternator's three phases U, V, W into a D.C. voltage. For each phase U, V, W, the rectifier includes a pair of Zener diodes 8a, 8b connected in series, phase terminal U, V, W being situated between them. The D.C. current is picked up at terminals B+ and B−. The circuit illustrated in FIG. 1 is, as a rule, configured using individual discrete components 8a, 8b.

Converter modules in which the converter valves (diodes) and the contacts are situated on top of one another in a stack are described in German Patent Application No. DE 100 09 171. The converter valves are implemented here in the form of un-encapsulated semiconductor chips. In manufacturing, the conventional converter modules, pre-fixing elements, which are, for example, lined with synthetic resin, are necessary for positioning the contacts and the housing components. This configuration of the converter modules is relatively expensive and complicated. In addition, a triple-phase converter module generates a relatively large amount of heat loss in a small space, which may not be dissipated sufficiently.

### SUMMARY

Therefore, it is an object of the present invention to provide a converter module which has a much simpler design and which generates less heat loss.

In accordance with an example embodiment of the present invention, a single-phase converter module is provided, having multiple terminals and at least two semiconductor chips which are situated on top of one another in a stack. At least one of the terminals is made up of a contact plate including a bar-shaped terminal lug attached to it. The terminal lug is positioned asymmetrically on the contact plate (i.e., its longitudinal axis is situated offset to a parallel axis running through the contact plate's center of gravity). An auxiliary element is provided at the end of the terminal lug which prevents the terminal from tilting about the terminal lug's longitudinal axis. This makes it possible to position the terminal's contact plate on a semiconductor chip without becoming canted. The auxiliary element may be detached after the stack system is assembled.

According to an example embodiment of the present invention, the auxiliary element has an aperture with which the appropriate terminal may be positioned in a joining device. A joining device according to the present invention has, for example, multiple guide pins and locating pins at which the terminals are aligned and held to make the stack system's assembly easier. For aligning the terminals, a guide pin and a locating pin preferably engage in the aperture provided in the auxiliary element.

According to a preferred embodiment of the present invention, the phase terminal is configured identically to the positive or negative terminal, i.e., the positive or negative terminal and the phase terminal are identical parts. In this way, the converter module may be substantially simplified and its price reduced.

The auxiliary elements provided at the terminals are preferably detached after the converter module is assembled.

The bar-shaped terminal lugs are preferably situated offset with respect to a face created by the contact plate. If the offset between the terminal lugs and the contact plates amounts to approximately one half of the height of a stack made up of one contact plate, one semiconductor chip, and two electrical connecting layers on both sides of the semiconductor chip, the terminal lugs may then be brought out from the converter module on the same level, provided identical terminals are used for the positive terminal or negative terminal and the phase terminal. This achieves advantages with regard to the manufacturing process if the converter module is packaged in a standard plastic housing.

The converter module is preferably packaged in a standard plastic housing which is manufactured in an injection molding process. This type of packaging is particularly cost-effective.

### BRIEF DESCRIPTION OF THE DRAWINGS

The present invention is explained in greater detail below in an example based on the figures.

FIG. 1 shows a conventional rectifier bridge circuit including Zener diodes.

FIG. 2 shows a conventional system of rectifier diodes in a diode stack.

FIG. 3 shows a preferred embodiment of a single-phase converter module according to the present invention having a stack-like configuration.

FIG. 4 shows a ready packaged single-phase converter module.

FIG. 5 shows a line of multiple packaged converter modules.

### DETAILED DESCRIPTION OF EXAMPLE EMBODIMENTS

Regarding the explanation of FIG. 1, reference is made to the introductory part of the specification.

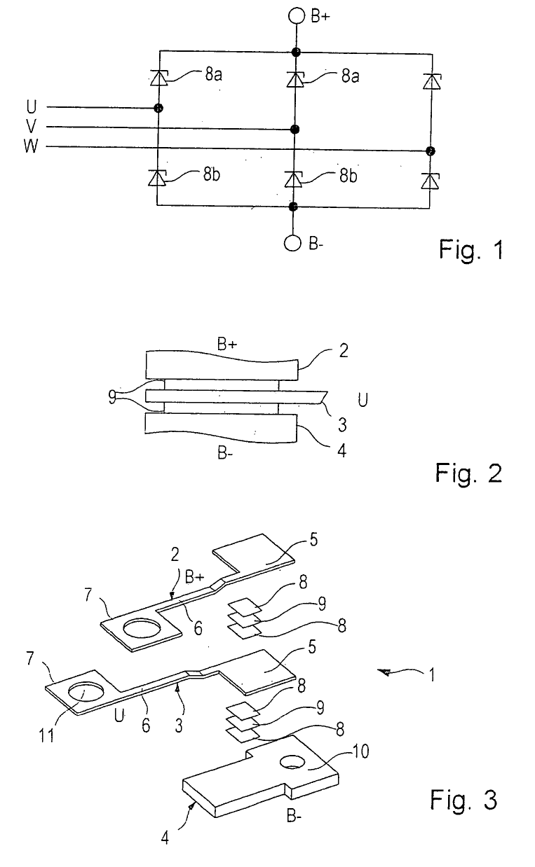

FIG. 2 shows a detail of a single-phase converter module 1 in which the converter valves (Zener diodes in the present example) are situated on top of one another in a stack in the form of semiconductor chips 9. The converter module includes a positive terminal 2 (B+), a negative terminal 4 (B−), and both semiconductor chips 9 having a phase terminal 3 situated between them. As is also recognizable in FIG. 2, semiconductor chips 9 have no housing.

In this case, negative terminal 4 is used simultaneously as an electric terminal, as a thermal capacitor for the back-up of peak power, as well as as a cooling terminal for dissipating the heat loss generated by the circuit.

In contrast to the triple-phase converter module described in German Patent Application No. DE 100 09 171, a multi-phase converter according to the present invention is made up of multiple individual single-phase converter modules. This has the advantage that the heat loss of a multi-phase converter circuit is not concentrated in such a small space and may be better distributed.

FIG. 3 shows a preferred embodiment of a single-phase converter module 1 in an exploded view. Converter module 1 includes a negative terminal 4 in the form of a metallic base (B−) which is used for mechanical stabilization and for mounting converter module 1 on a heat sink. For this purpose, negative terminal 4 includes an aperture 10 for mounting module 1 on the heat sink, by screwing on, riveting, etc.

Converter module 1 is preferably assembled in a joining device in which the individual elements of module 1 may be located and accurately positioned. The joining device may, for example, simultaneously be used as a soldering form for soldering the component/contact stack. First lower diode 9 (negative chip), then phase terminal 3, then upper diode 9 (positive chip), and finally positive terminal 2 (B+) are stacked onto base 4 during assembly of converter module 1.

The electrical connection of elements 2 through 4, 9 is established via soldering foils 8 which are situated on both sides of a semiconductor chip 9. Other standard connecting techniques such as, for example, application of conductive adhesive, soldering paste, etc. may optionally also be used.

Positive terminal 2 and phase terminal 3 are made up of a contact plate 5 having a bar-shaped terminal lug 6 and an auxiliary element 7. Bar-shaped terminal lug 6 is positioned asymmetrically on contact plate 5 (i.e., the longitudinal axis of bar-shaped terminal lug 6 is situated offset to a parallel axis running through the contact plate 5's center of gravity). Auxiliary element 7, provided at the other end of bar-shaped terminal lug 6, is designed in such a way that terminal 2, 3 does not tilt about the longitudinal axis of the bar-shaped terminal lug when the contact, for example, is supported at one point along bar-shaped terminal lug 6. This has the advantage that contact plates 5 of terminals 2, 3 may be applied planarly on semiconductor chips 9, without terminals 2, 3 subsequently becoming canted.

Furthermore, terminals 2, 3 have a positioning aperture 11 which is preferably situated in auxiliary element 7 to be able to accurately align terminals 2, 3 at a stop of the joining device. A positioning pin, for example, of the joining device engages in shown positioning apertures 11 during assembly of the converter module.

After assembly of converter module 1, auxiliary elements 7 may be detached, if needed.

As is also recognizable in FIG. 3, terminals 2 and 3 have an identical design, positive terminal 2 and phase terminal 3 being situated rotated by 180° with respect to the longitudinal axis of terminal lugs 6. In this way, converter module 1 may be manufactured in a particularly simple and cost-effective manner.

Furthermore, the bar-shaped terminal lugs of positive terminal 2 and phase terminal 3 are situated offset to the plane created by a contact plate 5. With respect to contact plate 5, bar-shaped terminal lugs 6 are offset parallel to one another, preferably by one half of the height of a stack made up of contact plate 5 of positive terminal 2, one semiconductor chip 9, and two soldering layers 8. This design makes it possible to bring out terminal lugs 6 of positive terminal 2 and of phase terminal 3 from module 1 on the same level. In addition, it is possible to use identical parts for positive terminal 2 and phase terminal 3.

Subsequent to its assembly and soldering, single-phase converter module 1 is packaged in a standard plastic housing 12.

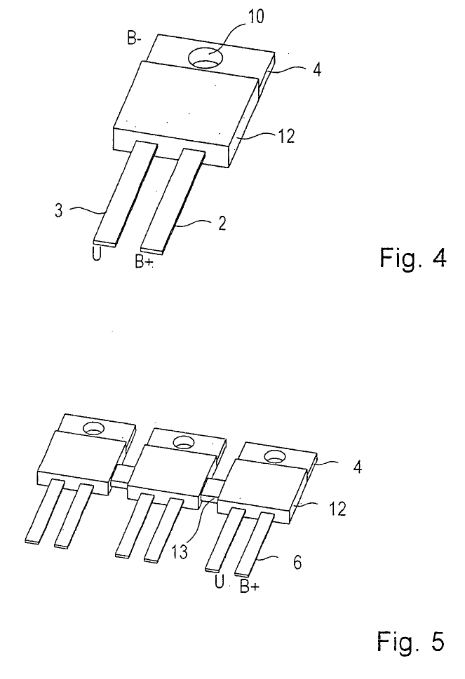

FIG. 4 shows packaged converter module 1 in a design similar to a transistor. Housing 12 shown is manufactured in a standard mold process (injection molding process). As is recognizable, converter module 1 is only packaged in the area of the chip/contact stack. Terminals 2, 3 and a mounting section of negative terminal 4 including mounting aperture 10, however, protrude from housing 12. Auxiliary elements 7 have already been detached in the illustrated state of converter module 1.

FIG. 5 shows multiple packaged converter modules 1 according to FIG. 4 which are connected to one another via a separable connection, in particular separable by hand (by twisting for example). For this purpose, the connection between the single-phase modules may be weakened, for example (via perforation). The desired number of single-phase converter modules 1 may thus simply be detached during the final assembly of a converter.

In the illustrated embodiment of the present invention, housings 12 of converter modules 1 are connected to one another via plastic bars 13 which are also manufactured in an injection molding process, preferably in one working step together with housings 12. Converter modules 1 may, for example, optionally also be positioned on a shared carrier foil and packaged.

Individual converter modules 1 of a module line are preferably such modules that have been either subjected to a complete electrical check prior to packaging and appropriately sorted, or manufactured directly in sequence, thus having similar electrical properties. This ensures that individual converter modules 1 of a line have only minor electrical deviations from one another.

1-10. (canceled)

11. A converter module, comprising:
a positive terminal, a negative terminal, a phase terminal, a first semiconductor chip and a second semiconductor chip, the positive terminal, negative terminal, the phase terminal, the first semiconductor chip, and the second semiconductor chip being situated on top of one another in a stack;
wherein at least one of the positive terminal, the negative terminal, and the phase terminal includes a contact plate, a bar-shaped terminal lug which is positioned asymmetrically on the contact plate, and an auxiliary element which prevents the at least one of the positive terminal, the negative terminal, and the phase terminal from tilting about a longitudinal axis of the terminal lug, the auxiliary element being able to be detached after the converter module is assembled.

12. The converter module as recited in claim 11, wherein the phase terminal is configured identically to one of the positive terminal or the negative terminal.

13. The converter module as recited in claim 11, wherein the bar-shaped terminal lug is situated offset with respect to a plane created by the contact plate.

14. The converter module as recited in claim 13, wherein at least two of the positive terminal, the negative terminal, and the phase terminal includes a respective bar-shaped terminal lug, each bar-shaped terminal lug being situated offset so that the respective terminal lugs may be brought out from the converter module on a same level.

15. The converter module as recited in claim 11, wherein the converter module is situated in an injection molded plastic housing.

16. The converter module as recited in claim 11, wherein the auxiliary element has a positioning aperture for positioning the auxiliary element in a joining device.

17. A line of multiple single-phase converter modules, comprising:
a plurality of converter modules, each of the converter modules including a positive terminal, a negative terminal, a phase terminal, a first semiconductor chip and a second semiconductor chip, the positive terminal, negative terminal, the phase terminal, the first semiconductor chip, and the second semiconductor chip being situated on top of one another in a stack;
wherein at least one of the positive terminal, the negative terminal, and the phase terminal includes a contact plate, a bar-shaped terminal lug which is positioned asymmetrically on the contact plate, and an auxiliary element which prevents the at least one of the positive terminal, the negative terminal, and the phase terminal from tilting about a longitudinal axis of the terminal lug, the auxiliary element being able to be detached after the converter module is assembled.

18. A method for manufacturing a converter module comprising:
providing a positive terminal, a negative terminal, a phase terminal, a first semiconductor chip and a second semiconductor chip, at least one of the positive terminal, the negative terminal, and the phase terminal having a contact plate, a bar-shaped terminal lug, and an auxiliary element, the terminal lug being positioned asymmetrically on the contact plate, the auxiliary element preventing the terminal from tilting about a logitudinal axis fo the bar-shaped terminal lug;
stacking the positive terminal, the negative terminal, the phase terminal, the first semiconductor chip and the second semiconductor chip on top of one another in a joining device, the phase terminal being situated rotated by 180° relation about the terminal axis of the terminal lug; and
encapsulating the stack in an injection molded housing.

19. The method as recited in claim 18, wherein at least one of the position terminal, the negative terminal and the phase terminal is positioned in the joining device using an aperture provided in the auxiliary element.

20. The method as recited in claim 18, wherein the positive terminal or the negative terminal and the phase terminal are identical parts which are inserted into the joining device rotated by 180°.
